(19) United States
(12) Patent Application Publication
(10) Pub. No.: US 2008/0046799 A1
(43) Pub. Date: Feb. 21, 2008

(54) Method for Iteratively Decoding Block Codes and Decoding Device Therefor

(76) Inventors: Benoit Geller, Paris (FR); Jean-Pierre Barbot, Issy Les Moulin Eaux (FR); Jean-Marc Brossier, Le Champ-Pres-Pro-Ges (FR); Christophe Vanstraceele, Cachan (FR)

Correspondence Address: YOUNG & THOMPSON, 745 SOUTH 23RD STREET, 2ND FLOOR, ARLINGTON, VA, 22202, US

(21) Appl. No.: 11/628,851

(22) PCT Filed: Jun. 6, 2005
(86) PCT No.: PCT/FR05/01377

§ 371 Date: Oct. 5, 2007

(30) Foreign Application Priority Data
Jun. 10, 2004 (FR) 0406291

(51) Int. Cl. H03M 13/05

(52) U.S. Cl. 714/777; 714/E11.032

(57) ABSTRACT

Each received word is subjected to SISO turbodecoding consisting in generating decoded test words using an iterative algorithm, calculating the analog weight of the decoded test word, which weight is the half-sum of the products of the value of each bit mapped to ±1 of this decoded test word and the log-likelihood of this bit, classifying the analog weight values of the concurrent words according to a first analog weight vector and a second analog weight vector formed by the analog weight components of the decoded test words, the bit of rank j of which is at a first value, and a second analog weight vector formed by the analog weight components of the decoded test words, the bit of rank j of which is at a second value, and calculating the SISO decoding soft-decision output value as being the difference between the analog weight components of the first and second vectors.

Methods for the coding/decoding of digital signals were introduced in order effectively to transmit digital data conveyed thereby.

In principle, these methods consist in adding to significant bits—the medium for the data conveyed by the aforementioned digital signals—redundancy of known bits in order to allow, following complete transmission and the introduction of errors inherent in the transmission process, decoding and reconstruction of the significant bits with good likelihood probability.

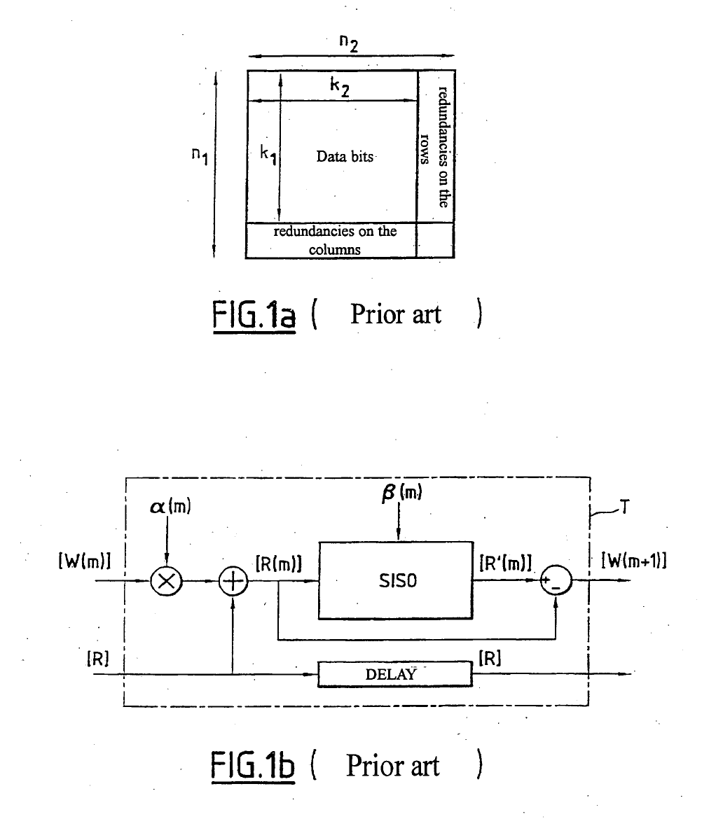

In the more specific case of block codes, including product codes, there will be considered, with reference to FIG. 1a, two block codes C₁ (n₁, k₁, d₁) and C₂ (n₂, k₂, d₂), the n bits of which, n=n₁×n₂, are placed in a matrix with k₁ rows and k₂ columns, k₁×k₂ designating the significant bits placed in a matrix with k₁ rows and k₂ columns, the n₁ rows being coded by the code C₂ and the n₂ columns being coded by C₁.

The parameters of the product code P(n, k, d) are given by n=n₁×n₂, k=k₁×k₂, d=d₁×d₂ and the rate of the product code is given by r=r₁×r₂, which is the product of the rates of the codes C₁ and C₂.

The decoding after reception of a received product code word R={r₁ . . . rₙ} of a single row or of a single column E={e₁, . . . eₙ} coded by the code C₁ or C₂ is expressed in the form R=E+G, wherein G={g₁, . . . gₙ} designates additive white Gaussian noise introduced via the transmission channel.

The maximum likelihood of the received code word R relative to a product code word is obtained by the optimum decision D={d₁, . . . , dₙ} verifying the equation:
D=min_{Ci}∥R−Cⁱ∥²

equation in which

Cⁱ={c₁, . . . cₙ} designates a code word, and

$${‖ R - {C}^{i} ‖}^{2} = {\sum }_{l = 1}^{n} {( {r}_{l} - {c}_{l}^{i} )}^{2}$$

designates the Euclidian distance of the considered word Cⁱ from the received code word R.

As an exhaustive search of all of the code words is impracticable, in order to find the optimum decision, a decoding process proposed by R. Pyndiah consists in using a Chase algorithm to obtain the decision.

For any hard decision wherein Y={y₁, . . . yₙ} relates to a received word R, the aforementioned algorithm consists in performing the following operations:
selection of p=d/2, d designating the number of least reliable bits, from the log-likelihoods rⱼ of low absolute value of a row or a column;
construction of the T^{q} test vectors, T^{q} representing all of the combinations of binary values in the p least reliable positions and a zero value for the other positions;
construction of the test words Z^{q}=Y⊕T^{q}, wherein the sign ⊕ designates the exclusive OR operation on the components of the vectors;
hard decoding of the test words Z^{q} in order to obtain words C^{q} pertaining to the code;
selection of the code word C^{d} pertaining to the code of minimum Euclidian distance from the received word and obtaining of the optimum decision D.

The reliability of this optimum decision then has to be calculated.

The aforementioned reliability in terms of log-likelihood (LLR) is given for each bit dⱼ of the optimum decision D, by the equation:

$$Λ ( d j ) = ln ( \frac{P \{ e j = + 1 / R \}}{P \{ e j = - 1 / R \}} )$$

wherein

P{eⱼ=ε/R}, ε=±1, designates the conditional probability that the bit eⱼ corresponds to the mapped value, given the received code word R;

In designates the Naperian logarithm.

Rigorous LLR calculation must allow for the fact that the optimum decision D is a word from among the 2^{k} (for k₁=k₂) words of the code C.

In the solution proposed by R. Pyndiah, an LLR approximation for signals having a high signal-to-noise ratio SNR is given by the equation

$${r}_{j}^{′} = \frac{{m}^{- 1 ( j )} - {m}^{+ 1 ( j )}}{4}$$

with
m^{+1(j)}=∥R−C^{+1(j)}∥²etₘ^{-1(j)}=∥R−C^{-1(j)}∥²

wherein
C^{+1(j)}={cₒ^{+1(j)}, . . . , cₙ^{+(j)}}et_{C}^{-1(j)}={cₒ^{-1(j)}, . . . , cₙ^{-1(j)}}

are the concurrent words of the code at a minimum distance from R, provided that the bit of rank j of these words is mapped to the value +1 or −1 respectively. The Chase algorithm allows the aforementioned concurrent words to be found. Should one of the words not exist, the reliability is fixed by a constant predetermined value β, the sign of which is given by the Chase decision. Increasing p increases the probability of finding, for a bit of rank j, the word concurrent with D.

Referring to FIG. 1b, in order to execute the turbodecoding from an SISO decoder, the data is therefore processed as follows: for a received product code word [R], the decoded product code word generated by the preceding iteration [R(m)] and the decoded product code word [R(m)] generated by the current iteration being delivered by the SISO decoder, the input word [W(m+1)] of the turbodecoding T for the following iteration verifies the equation:
[W(m+1)]=[R′m)−R(m)]
with [R(m+1)]=[R]+α(m+1)[W(m+1)]
and [R(1)]=[R] for the first iteration.

In the foregoing equation, W(m) designates the extrinsic data, normalized to 1 at each iteration, and α(m) designates a coefficient, which is dependent on the current iteration, of rank m.

This is an almost optimum decoding process insofar as the data circulating from one decoding iteration to the next contains only the data provided by this iteration, owing to the subtraction operation performed, the extrinsic data alone being transmitted.

For a more detailed description of this turbodecoding process, reference may usefully be made to patent application EP 0 827 284, published on 4 Mar. 1998.

The manner in which the aforementioned coding process, for a row or a column, is carried out may be summarized as follows:
a) iterative process according to the Chase algorithm with decoding using a Berlekamp-Massey or PGZ-type algorithm and storage of the words obtained and the weight thereof;
b) search from among these words for the hard decision C^{d}=D, the optimum decision at a minimum Euclidian distance;
c) for each bit of rank j, search for the concurrent word C^{c} at a minimum distance from R such that cⱼ^{d}≠cⱼ^{c} and calculation of the reliability, in terms of log-likelihood, from the approximation

$${f}_{j} = [ \frac{{m}^{c} - {m}^{d}}{4} ] ;$$
d)—calculation of the extrinsic data for the concurrent word of rank j retained at step c), by the equation
   wj=|fj−cⱼ^{d}·r′j|·cⱼ^{d}

In the foregoing equation, cⱼ^{d} designates the bit of rank j of C^{d}=D and r′j designates the log-likelihood of the soft decision R′ delivered by the SISO decoder.

The embodiment according to the method described by R. Pyndiah requires the actual storage of 2^{p} words of n bits at step a) for each decoded row or column.

Furthermore, once the aforementioned step has been executed, the implementation of steps c) and d) requires, for each step, a loop calculation to be carried out in order to distinguish the hard-decision code word or the concurrent word, respectively, at a minimum distance from the received product code word R.

Operations of this type are highly costly in terms of resources and calculating time and can be only performed easily using very high-power computing means.

The present invention seeks to remedy the drawbacks of the method of the above-described prior art.

In particular, the present invention seeks substantially to eliminate the operation of storing the product code words by the implementation of the iterative process, according to the Chase fast algorithm for example, in order, in particular, to allow decoding devices to be implanted in equipment having a much lower computing capacity, not exceeding, for example, the capacity of hand-held computers, mobile telephony terminals or even personal digital assistants, or else in digital data storage systems.

Finally, the present invention also seeks, by introducing the aforementioned simplification, to utilize a method and a device for iteratively decoding block codes in which the iterative process is reduced to a single loop, the loop processing of steps c) and d) of the prior-art method being substantially eliminated, thus significantly reducing the calculating time for carrying out the decoding, increasing the number of test code words used for the decoding, or else increasing the length of the processed code.

The method for iteratively decoding block codes by the SISO decoding of a received product code word from decoded test words, according to the present invention, is notable in that said method consists at least in generating a plurality of decoded test words using an iterative process, calculating, for each decoded test word, the analog weight expressed as the half-sum of the products of the value of each bit mapped to within + or −1 of this decoded test word and the probability of this value, in terms of log-likelihood, classifying and storing said analog weight values, in order to produce a first analog weight vector formed by the analog weight components of the decoded test words, the bit of rank j of which is at a first value, and a second analog weight vector formed by the analog weight components of the decoded test words, the bit of rank j of which is at a second value, calculating the SISO decoding soft-decision output value expressed as the difference between the analog weight components of the first and the second analog weight vector.

The device for iteratively decoding block codes by the SISO decoding of a received product code word from decoded test words, according to the present invention, is notable in that it comprises, at least for the processing of each received product code word, a module for generating, from an iterative algorithm, a plurality of decoded test words, a module for calculating, for each decoded test word, the analog weight expressed as the half-sum of the products of the value of each bit mapped to within the value +1 or −1 of this decoded test word and the probability of this value, in terms of log-likelihood, a module for sorting, by classification, the analog weight values for the decoded test words in order to produce a first analog weight vector formed by the analog weight components of the decoded test words, the bit of rank j of which is at a first value, and a second analog weight vector formed by the analog weight components of the decoded test words, the bit of rank j of which is at a second value, a first and a second register for storing said analog weight values classified according to this first or this second analog weight vector, respectively, and a module for calculating the SISO decoding soft-decision output value, comprising at least one module for subtracting the analog weight components from the first and the second analog weight vector.

The method and the device for iteratively decoding block codes according to the present invention are used for the implementation thereof, in the form of an integrated circuit, in any equipment for receiving digital signals and, in particular, in light equipment of low overall size and having limited computing resources.

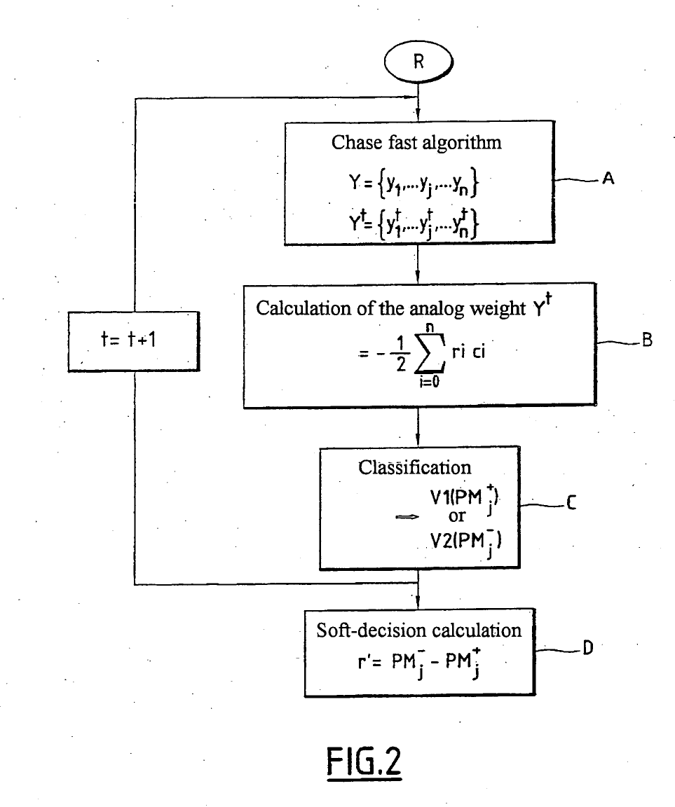

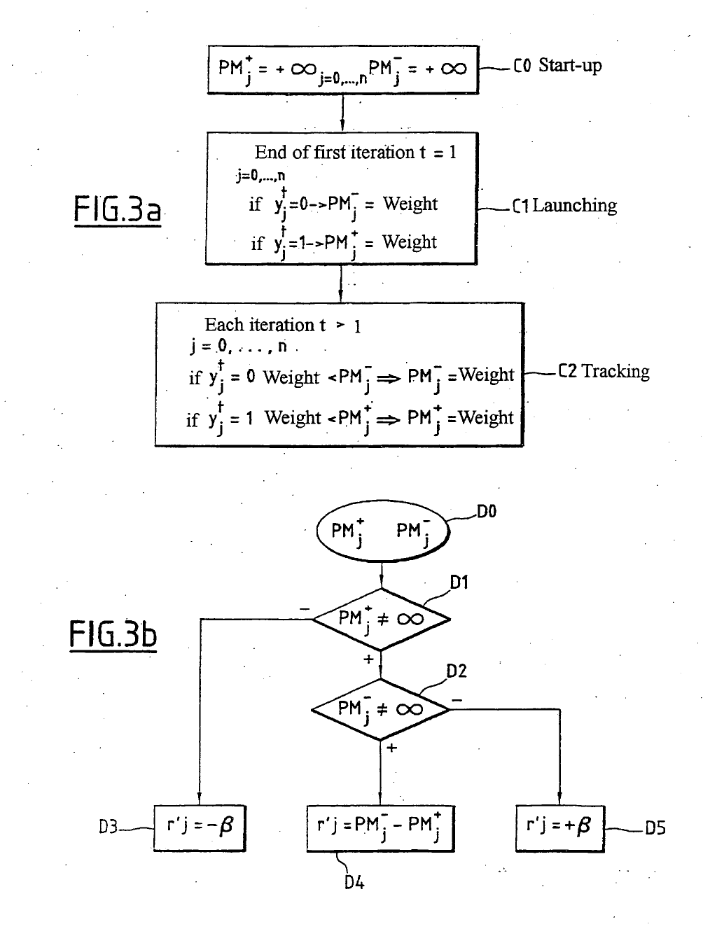

The method and the device will be better understood on reading the description and on examining the following drawings in which, in addition to FIGS. 1a and 1b which relate to the prior art:
FIG. 2 shows, by way of example, a flow chart of the essential steps for carrying out the iterative decoding method according to the present invention;
FIG. 3a shows, by way of example, a detailed flow chart of the step of classifying the analog weight values of the decoded test words illustrated in FIG. 2; and
FIG. 3b shows, by way of example, a detailed flow chart of the step of calculating the soft-decision value illustrated in FIG. 2.

Before the actual description of the block code iterative decoding method according to the present invention, the embodiment of the Chase fast iterative method will firstly be recalled. The Chase fast iterative method will be taken as a non-limiting exemplary embodiment of an iterative algorithm for generating decoded test words for carrying out the method according to the invention.

The aforementioned method or Chase fast iterative algorithm simplifies the operations of the Chase process, previously mentioned in the description, by scanning the test vectors using Gray-type counting. This mode of operation simplifies the expression of the syndrome calculated for each iteration, the notion of syndrome corresponding to the notion of error location after coding, by taking advantage of the properties of the linear block codes. The calculation of the weight for each test vector is also simplified owing to the simplification of updating, given that only a single bit has to be changed.

Introduction of the variables used in the Chase fast method.

In the aforementioned embodiment:
H designates the control matrix of the BCH 1 correcting code used by way of example. As m designates the order of the Galois field, H has m columns and 2^{m}−1=n rows. The calculated syndrome is given by the equation S=YH, Y designating the decision obtained by hard decoding on the input word. Hᵢ designates the i^{th} row of the matrix H. The code is a Hamming code extended by a parity bit denoted by y₀. The parity bit is not taken into account in the calculation of the syndrome but is controlled afterwards.

It will be noted that if a single bit of arbitrary rank Y is changed, the new syndrome is obtained merely by the addition to the former syndrome, modulo-2 addition, of the aforementioned vector Hᵢ corresponding to the bit of rank i. The Gray counting introduced to distinguish the test vectors allows only a single bit to be changed per iteration and accordingly simplifies the calculation of the syndrome S in a particularly significant manner.
R={r₀, . . . , rₙ} designates the soft input of the word received from the SISO decoding and R′={r′₀, . . . , r′ₙ} designates the soft output of the SISO decoding.
Y={y₀, . . . , yₙ} designates the hard decision of the soft-input word R from the SISO decoder, wherein yᵢ∈{0, 1}. Under these conditions, Y^{bm}={y₀^{bm}, . . . , yₙ^{bm}} designates the vector tested at each iteration of the Chase fast algorithm, allowing scanning of the space of all of the possible words around the word received by the previously introduced Gray counting, Y^{t}={y^{t}₀, . . . , y^{t}ₙ} designating the word obtained by hard decoding.
Weight^{bm} and Weight designate the analog weights of Y^{bm} and Y^{t} respectively, the vector tested at each iteration and the word obtained by hard decoding.
Bm={Bm₁, . . . , Bm₂ₚ₋₁} designates the set of the numbers of the modified bits of a following test word from the received word in order to scan the space around the received word when using the Chase fast algorithm. This operation is equivalent to Gray binary counting on the test vectors. p designates the number of least reliable positions taken into account in the Chase fast algorithm. For example, for p=3, if the least reliable positions are {3, 5, 9}, then Bm={3, 5, 3, 9, 5, 3}.

⊕ designates the addition of the modulo-2 bits (exclusive OR), this operation carrying out bit by bit. The development of the chase fast method is set out in the following table:

| | |
|---|---|
| A) | Start-up |
| | Variables |

The aforementioned variables used are started as follows :
Y^{bm} = Y and Weight^{bm}=0 (the first word tested by the algorithm is the received word,
and the weight is considered to be zero for the received word)
Y^{t} = Y and Weight = 0 (Y^{t} is started at the value of the first tested word before being
decoded in the next step)

Hard decoding

Calculation of the syndrome : S = Y^{t}H

If S ≠ 0 then [symbol]
Determination of the position of the error e by correspondence table then
correction by:
y^{t}ₑ ⊕ 1 → y^{t}ₑ
and updating of the weight by:
Weight − (2y^{t}ₑ −1) rₑ → Weight.
Correction of the parity bit
Calculation of b = y^{t}₁ ⊕ ... ⊕ y^{t}ₙ
If b ≠ y^{t}₀ then [symbol]
correction by:
y^{t}₀ ⊕ 1 → y^{t}₀
and updating of the weight by:
Weight − (2y^{t}₀ − 1) r₀ → Weight.
Obtained at this moment is the word Y^{t} obtained by hard decoding of the received

word Y and the analog weight thereof. This is the first test word and it is stored.

| | |
|---|---|
| B) | Iterations of the algorithm |

At each new iteration, the variables preserve the values that they had at the end of
the preceding iteration and, for t = 1 to t = 2^{p} −1, the following operations are
performed:

Modification of the bit to obtain the following word

The word to be tested for the current iteration is obtained from the word of the
preceding iteration by the modification of a single bit determined by the vector Bm:
y_{Bm(t)}^{bm} ⊕ 1 → y_{Bm(t)}^{bm}
The weight of the tested vector is updated:
Weight^{bm} −(2y^{t}_{Bm(t)} − 1)r_{Bm(t)} → Weight^{bm}
Y^{t} = Y^{bm} and Weight = Weight^{bm} (Y^{t} is started at the value of the first tested word
before being decoded)

Hard decoding

The new syndrome can be deduced very simply from the preceding one, as a single
bit has been modified : S ⊕ H_{Bm(t)} → S

If S ≠ 0 then [symbol]
Determination of the position of the error e by correspondence table then
correction by:
y^{t}ₑ ⊕ 1 → y^{t}ₑ
and updating of the weight by:
Weight − (2y^{t}ₑ −1) rₑ → Weight.
Correction of the parity bit
Calculation of b = y^{t}₁ ⊕ ... ⊕ y^{t}ₙ
If b ≠ y^{t}₀ then [symbol]
correction by:
y^{t}₀ ⊕ 1 → y^{t}₀
and updating of the weight by:
Weight − (2y^{t}₀ − 1) r₀ → Weight.
There is obtained the word Y^{t} produced by the hard decoding of the tested vector

Y^{bm} and the analog weight thereof. The current test word Y^{t} and the weight thereof
are then saved.

The index i is incremented and the step “Iterations of the algorithm” is returned to.
Modification of the bit to obtain the following word:
The reliabilities are then calculated in the same way as indicated hereinbefore

using the previously stored vectors.
In the equations of the table, the symbol → represents the operation of allocating a
value to a variable.

The method for iteratively decoding block codes according to the present invention will now be described in conjunction with FIG. 2.

With reference to the aforementioned FIG. 2, it will be noted that the decoding method according to the invention consists, for any received product code word R having the form R={a₁, . . . , aⱼ, . . . aₙ} wherein the components aⱼ of R designate the analog values of R detected after transmission or reading, in generating at a step A, by an iterative process such as the Chase fast algorithm, a plurality of decoded test words denoted by Y^{t}={y₁^{t}, . . . , yⱼ^{t}, . . . , yₙ^{t}}.

The decoded test words Y^{t} are obtained from a row or a column of the received product code word R. These operations are then applied sequentially to all of the rows or all of the columns following the iteration in question.

Firstly, a hard decision Y is made on the received produced code word R and values for the bits of Y, 0 or 1 (or −1 or +1 according to the convention retained) are therefore decided from the soft values without decoding.

By way of example, for a received row or column vector VR={−0.1; 0.55; 0.2; −0.6}, the retained hard decision Y is Y={0; 1; 1; 0} or {−1; +1; +1; −1} according to the chosen convention.

Secondly, the test vectors are generated, by modifying the p bits selected as being those least reliable, on the aforementioned non-decoded hard decision Y, according to all of the possible binary combinations. The decoded test words Y^{t} are then obtained by hard decoding the aforementioned test vectors.

Among all of these combinations, the combination wherein the p least reliable bits are not changed corresponds to the decoded test word Y^{t} obtained by direct decoding of the hard decision Y.

The following decoded test words are obtained from the hard decision Y in which the p least reliable bits are modified to obtain a test vector which is subjected to hard decoding.

The method according to the invention consists, in particular, in generating 2^{p} decoded test words for the 2^{p} bits of the decoded received word Y derived from the hard decoding, the value of which is the least reliable.

It will be understood, in particular, that carrying out the aforementioned Chase fast algorithm provides the above-described decoded test words Y^{t} corresponding to the abovementioned test words.

The step A is then followed by a step B represented in FIG. 2, consisting in calculating for each decoded test word Y^{t} the analog weight expressed as the half-sum of the products of the value of each bit mapped to within the value ±1 of this decoded test word and the probability of this value in terms of log-likelihood.

It will be noted, with reference to the table introduced hereinbefore, that the analog weights of the decoded test words Y^{t} have been obtained, as indicated in the aforementioned table.

The analog weight, denoted generically by Weight for the decoded test words, then verifies Equation (15):

$$Weight = - \frac{1}{2} {\sum }_{i = 0}^{n} {r}_{i} {c}_{i} \qquad ( 15 ) .$$

In the foregoing equation:

rᵢ designates the log-likelihood value of the corresponding bit of rank i, i being a calculation index corresponding in fact to the index of the bit mapped to within the value +1 or −1, respectively, and cᵢ designates this mapped value for each decoded test word Y^{t}.

The mode of calculating the analog weight at step B and the expression of said weight for carrying out the iterative decoding method according to the present invention will now be justified.

For the concurrent words C^{+1(j)} and C^{-1(j)}, concurrent words at the minimum distance from the received product code word R according to the decoding method of the prior art of R. Pyndiah, the definition of the analog weights is given by:
m^{+1(j)}=∥R−C^{+1(j)}∥²etₘ^{-1(j)}=∥R−C^{-1(j)}∥²

The value of the log-likelihood for each concurrent word is given by the equation:

$${r}_{j}^{′} = \frac{{m}^{- 1 ( j )} - {m}^{+ 1 ( j )}}{4}$$

However, these same values are expressed by the equations

$$\begin{matrix}{m}^{+ 1 ( j )} = {\sum }_{i = 0}^{n} {( ri - ci + 1 ( j ) )}^{2} = {\sum }_{i = 0}^{n} ( {ri}^{2} + 1 - 2 ri {ci}^{+ 1 ( j )} ) \\ {m}^{- 1 ( j )} = {\sum }_{i = 0}^{n} ( {r}_{i}^{2} + 1 - 2 ri {ci}^{- 1 ( j )} )\end{matrix}$$

Accordingly, the value of the log-likelihood can be expressed in the form of Equation (16)

$${r}_{j}^{′} = ( - \frac{1}{2} {\sum }_{i = 0}^{n} ri {ci}^{- 1 ( j )} ) - ( - \frac{1}{2} {\sum }_{i = 0}^{n} ri {ci}^{+ 1 ( j )} ) \qquad ( 16 )$$

The introduction of the definition of the new analog weight Weight for each decoded test word by Equation (15) given hereinbefore in the description therefore allows the same classification order that the conventional definitions of the prior art had to be preserved.

As a result, the expression of the analog weight mentioned hereinbefore in Equation (15) can therefore advantageously be used to classify the decoded test words generated by the Chase fast algorithm.

In the specific case of the Chase fast process, all of the possible combinations of the test vectors, which have not yet been decoded, are obtained by modifying a single bit of the test vector of the preceding iteration t in order to obtain the following test vector of the current iteration t+1, etc., from the first test vector, in order to obtain all of the possible combinations of these bits on the selected positions.

In order not to return to the same vector a plurality of times, or to forget a vector, the bits of the test vector of the preceding iteration are modified, in a proportion of a single one of said bits according to a specific sequence from a Gray counting, allowing all of the possible bit combinations to be reviewed. The order in which the bits are changed is contained in a vector adhering to this counting mode.

The fact that only a single bit is changed at each iteration allows the weight P′ of the new test vector for the current iteration t+1 to be obtained from the preceding iteration t according to the equation:
P′=P−rₖc′ₖ (17)

wherein P designates the weight of the test vector of the preceding iteration, rₖ designates the reliability, in terms of log-likelihood, of the modified bit of rank k, and c′ₖ the new value mapped to within ±1 of the modified bit of rank k.

The decoded test word of the current iteration is obtained by hard decoding the test vector in question of this same iteration.

In view of the fact that the hard decoding modifies, if appropriate, only a single bit at a time, if the decoded test word does not pertain to the code, the updating of the weight according to Equation (17) can then also be used to obtain the analog weight of the decoded test word Y^{t}.

The method for calculating the analog weight referred to hereinbefore in the description in conjunction with step B therefore allows, in accordance with a particularly notable aspect of the method according to the present invention, the SISO decoding soft output value to be calculated according to Equation (16) cited hereinbefore in the description, while preserving each time the minimum distance, provided that the j^{th} bit of the concurrent word is at the value mapped to within the value +1 or −1 for j=0 to n.

Accordingly, following step B of FIG. 2, the iterative decoding method according to the present invention consists in classifying and, of course, storing the analog weight values for the decoded test words so as to produce a first analog weight vector V₁ formed by the analog weight components PMⱼ⁺ of the decoded test words, the bit of rank j of which is mapped to within a first value +1, and a second analog weight vector V₂ formed by the analog weight components PMⱼ⁻ of the decoded test words, the bit of rank j of which is mapped to within the second value −1.

The classification operation is represented symbolically at step C of FIG. 2 by the equation:
Weight→V₁(PMⱼ⁺) or V₂(PMⱼ⁻)

It will be understood, in particular, that steps A, B, C represented in FIG. 2 and, in particular, steps B and C can be integrated into the iterative method of the Chase fast algorithm, this iterative process being represented by the step of returning from step C to step A denoted by t=t+1 in FIG. 2. It will be understood that the index t designates the passing from the decoded test word generated at the current iteration to the decoded test word of the following iteration for the exploitation of the two decoded test words.

Once all of the analog weight values PMⱼ⁺ and PMⱼ⁻ have been classified in the form of the vectors V₁ and V₂, there can then be called up a soft-decision calculating, i.e. SISO decoding, step D expressed as the difference between the analog weight components of the first and second analog weight vectors V₁ and V₂.

The procedure for classifying the analog weight values for the decoded test words, step C of FIG. 2, will now be described in greater detail in conjunction with FIG. 3a.

With reference to the aforementioned figure, the classification procedure of the method according to the present invention comprises a step for starting the first analog weight vector V₁ and the second analog weight vector V₂, according to which each analog weight component PMⱼ⁺ for the first vector V₁ relating to the analog weight components of the decoded test words, the bit of rank j of which is at a first value, and respectively PMⱼ⁻ for the second analog weight vector V₂ relating to the analog weight components of the decoded test words, the bit of rank j of which is at the second value, is started at the value PMⱼ⁺=+∞ or PMⱼ⁻=+∞, respectively, for all of the values of j pertaining to 0 . . . n.

The start-up operation is represented symbolically by:
V₁=Weight min⁺={PM₀⁺, . . . , PMⱼ⁺, . . . , PMₙ⁺}
V₂=Weight min⁻={PM₀⁻, . . . , PMⱼ⁻, . . . , PMₙ⁻}

The vectors V₁ and V₂ representing the list of the analog weights of the decoded test words Y^{t} derived from the received word, with the j^{th} bit at the first value 1 and at the second value 0 respectively.

For j=0 . . . n, an actual start-up is therefore written as PMⱼ⁺=+∞ and PMⱼ⁻=+∞.

The list containing the minimum weights must be understood as such on account of the procedure implemented by the following steps C₁ and C₂ called up further to the start-up step C₀ and to the first iteration of the Chase fast algorithm denoted as C₁ in FIG. 3a.

The operation consisting in classifying and storing the analog weight values therefore consists in classifying the analog weight values of the first test word obtained in the analog weight vectors of the minimum weights as a function of the value of the bits of said test word, the first tested first test word having the minimum weight relative to the start-up arbitrary weight values.

The decoded test word in question is the test word Y^{t}.

What is known as the launching operation, carried out at the end of the first iteration at step C₁ is written as follows:
for j=0 . . . n,
if y^{t}ⱼ=0→PMⱼ⁻=Weight, the decoded test word Y^{t} being considered for the time being as that having a bit of rank j=0 at a minimum distance from the received word R.

If y^{t}ⱼ=1→PMⱼ⁺=Weight, the test word Y^{t} being considered as the word having the bit of rank j=1 at a minimum distance from the received word.

The launching step C₁ is then followed by a step C₂, known as the tracking step, the purpose of which is to iteratively examine all of the decoded test words Y^{t}. Thus, with reference to step C₂ of FIG. 3a, the classification procedure consists in classifying the actual weight obtained during the current iteration of the Chase fast algorithm in the first minimum analog weight vector V₁ or the second minimum analog weight vector V₂, respectively, if and only if the current weight Weight is less than the weight value present for the component of the same rank stored at the preceding iteration or at an earlier iteration.

The actual classifying operation is written as follows:
for j=0 . . . n,
if y^{t}ⱼ=0 and Weight<PMⱼ⁻→PMⱼ⁻=Weight
if y^{t}ⱼ=1 and Weight<PMⱼ⁺→PMⱼ⁺=Weight

In the equations indicated with the description of steps C₁ and C₂, it will be noted that the = sign indicates the allocation of the weight value to the variable when the inferiority condition is satisfied.

Finally, step D of FIG. 2, in which the SISO decoding output value is calculated, will now be described in greater detail in conjunction with FIG. 3b.

With reference to FIG. 3a, there is obtained at the end of step C₂ the vectors V₁ and V₂, lists of the analog weight values of the decoded test words with the j^{th} bit at 1 (first value) and at 0 (second value).

The calculating operation represented at step D of FIG. 2 therefore consists in calculating, from the values PMⱼ⁺ and PMⱼ⁻, for any bit of rank j pertaining to 0, n, of each decoded test word if the value of the analog weight components is different from the start-up value, i.e. +∞, the probability of the value of the corresponding bit of rank j as being the difference between the actual analog weight values PMⱼ⁻ and PMⱼ⁺.

The aforementioned condition can be met, by way of non-limitative example, by the tests D₁ and D₂, represented in FIG. 3b, of the difference between the values PMⱼ⁺ and PMⱼ⁻ at the aforementioned start-up value +∞.

It will be understood that the value +∞ can be represented by any value of arbitrary high size and incompatible with an actual value of likely analog weight. The difference test may in this case take the form of an inferiority test, for example.

The calculation of the difference between the analog weight values is represented at step D₄.

If not, if the value of the analog weight component PMⱼ⁻ of the decoded test word, the bit of rank j of which is at a value, the value 0 for example, is the only one different from the start-up value +∞, a given first negative value is allocated to the probability of the value of the bit of rank j. This operation can be carried out, as represented in FIG. 3b, in the event of a negative response to the test D₁ at a step D₃.

If not, if the value of the analog weight component PMⱼ⁺ of the decoded test word, the bit of rank j of which is at the other value, value 1 for example, is different from the start-up value, a given value, in opposition to the first given value, is allocated to the probability of the value of the bit of rank j. This operation is carried out in the event of a negative response to the test D₂ at step D₅.

The first and second given values, which are negative and positive respectively, are the values β, the turbodecoding weighting coefficient.

Additional memory may be saved in order to carry out the code decoding method produced by eliminating Y, i.e. the test word decoded after hard decoding forming the decoded test word for carrying out the algorithm. In this situation, only the test vector Y^{bm}, representing the test word, is used. This test word can be reallocated to its true value of the start of the iteration once it has been subjected to hard decoding to produce the corresponding test word, in order not to change the list of the test words, if the value of the erroneous bit and a variable indicating any parity error have been preserved. This operating procedure also eliminates the need to reallocate each time the value Y^{t} of the test word after hard decoding, i.e. the test word decoded at the value Y^{bm}.

Finally, the parity bit of each test word can be updated each time a bit of rank j is modified, thus obviating the need to add up all of the bits each time in order to recalculate the parity value.

The method according to the present invention is notable with regard to the methods of the prior art in that it allows a considerable gain in terms of the number of logic gates used and the actual calculating time required, while preserving the same computational result.

Firstly, exploiting the properties of the syndromes of the block codes within the Chase fast algorithm divides by n the calculating time of the syndrome in question. In fact, the number of operations required to calculate the analog weight is divided by the same factor, so, overall, the calculating time of the procedure for exploring all of the test vectors using the Chase fast algorithm is, in turn, divided by n.

Secondly, the new mode of operation for calculating reliabilities used in accordance with the present invention eliminates altogether the need to store the decoded test words examined by the iterative Chase fast algorithm procedure. With this mode of operation, it is accordingly not necessary to use an amount of memory corresponding to n×2^{p} bits, for each row or column of the product code, thus saving a total of n²×2^{p} bits for the decoding of the complete product code over a half-iteration. The amount of memory thus required to store the analog weights PMⱼ⁻ and PMⱼ⁺ is now dependent merely on the length of the code and the number of bits of the quantification and is accordingly in no way dependent on the number of concurrent words or test words chosen.

Moreover, as illustrated in FIG. 2, all of the operations are performed in a single loop for all of the bits of a row or a column of the code. This embodiment therefore allows very simple introduction of the decoding method according to the invention, and it is also possible to increase the number of decoded test words in order to improve the performance levels of the turbodecoding.

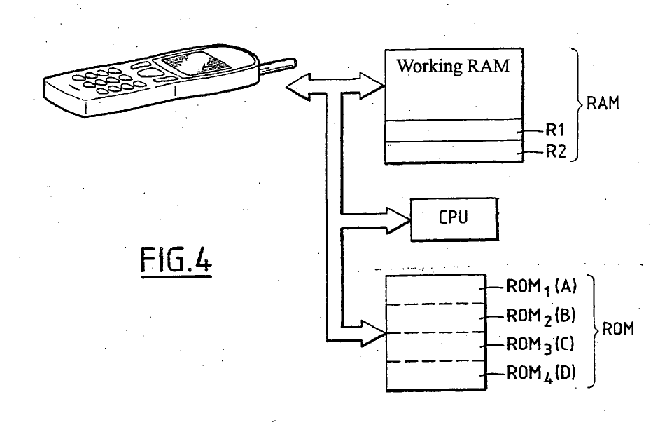

An above-described device for iteratively decoding block codes by the SISO decoding of a received code word R consisting of n bits from decoded test words, in accordance with the method according to the present invention, will now be described in conjunction with FIG. 4.

The device according to the invention is known, in a non-restrictive manner, to be integrated into a mobile telephony terminal, a personal digital assistant or a portable computer, for example.

This type of equipment conventionally comprises a central processing unit (CPU) formed by a microprocessor, a RAM, serving as the working memory and a permanent memory such as a ROM—a non-volatile memory, for example.

The device according to the invention represented in FIG. 4 also comprises a module for generating a plurality of decoded test words from an iterative algorithm such as the Chase fast algorithm.

It will be understood that the aforementioned generator module may consist of a program module recorded in the permanent memory ROM¹ and called up in the working memory RAM for executing the Chase fast algorithm described hereinbefore in conjunction with the table of the present description in accordance with step A) of FIG. 2.

It also comprises a module for calculating the analog weight of each decoded test word Y^{t} in accordance with step B of FIG. 2. The aforementioned calculating module may consist of a program module recorded in the permanent memory ROM₂ and called up in the working memory for execution in accordance with the equation indicated in step B) of FIG. 2.

It also comprises a module for sorting by classification the analog weight values for the aforementioned decoded test words Y^{t}. This sorting module may consist of a program module ROM₃ called up in the working memory RAM for execution in accordance with the method according to the invention represented in FIGS. 2 (step C) and 3a.

It comprises, according to a notable aspect of the device according to the invention, a first register R₁ and a second register R₂ for storing the analog weight values classified according to the first and the second analog weight vector V₁, V₂, each relating to the analog weight components of the decoded test words.

It will be noted, by way of non-limiting example, that the aforementioned registers may be configured as a protected memory zone of the working memory RAM or by an electrically reprogrammable non-volatile memory so as to allow reconfiguration of each register R₁, R₂ as a function of the number of decoded test words finally retained for carrying out the decoding.

The use of an electrically reprogrammable non-volatile memory provides separation, and therefore physical protection, of the analog weight vector data and the data processed in the RAM.

Finally, the device according to the invention comprises, as illustrated in FIG. 4, a module for calculating the SISO decoding soft-decision output value comprising at least one module for subtracting the analog weight components from the first and the second analog vector stored in the registers R₁ and R₂ respectively.

This calculating module may consist of a program module ROM₄ called up in the working memory for execution in accordance with the method according to the invention represented in FIGS. 2 (step D) and 3b.

Finally, the embodiment of the decoding device according to the present invention may advantageously be executed in chip form (dedicated integrated circuit).

The decoding method and device according to the invention are used, in particular, in the implementation of systems or equipment for storing coded data and for restoring this coded data in decoded form.

1. A method for iteratively decoding block codes by the SISO decoding of a received product code word (R) consisting of n bits, from decoded test words, wherein said method consists at least in:
generating a plurality of decoded test words using an iterative process;
calculating, for each decoded test word, the analog weight expressed as the half-sum of the products of the value of each bit mapped to within ±1 of this decoded test word and the probability of this value, in terms of log-likelihood;
classifying and storing said analog weight values for the decoded test words, in order to produce a first analog weight vector formed by the analog weight components of the decoded test words, the bit of rank j of which is at a first value, and a second analog weight vector formed by the analog weight components of the decoded test words, the bit of rank j of which is at a second value;
calculating the SISO decoding soft-decision output value as being the difference between the analog weight components of the first and the second analog weight vector.

2. The method as claimed in claim 1, wherein said method includes a step for starting the first and the second analog weight vector, each analog weight component PMⱼ⁺ for the first analog weight vector relating to the analog weight components of the decoded test words, the bit of rank j of which is at the first value, or PMⱼ⁻ for the second analog weight vector relating to the analog weight components of the decoded test words, the bit of rank j of which is at the second value, being started at the value PMⱼ⁺=+∞ or PMⱼ⁻=+∞, respectively, for any value of j=0 . . . n, the first and the second started analog weight vector containing the minimum weights.

3. The method as claimed in claim 1, wherein following the start-up step and the first iteration of the algorithm delivering the decoded test words, said operation consisting in classifying and storing said analog weight values consists in:
classifying the analog weight values of the first decoded test word obtained in the analog weight vectors of the minimum weights as a function of the value of the bits of this test word, the first decoded test word, which is the first tested, having the minimum analog weight relative to the arbitrary start-up weight values; and, for each current successive iteration,
classifying the current analog weight obtained during the current iteration in the first or the second analog weight vector, respectively, if and only if said current analog weight is less than the analog weight value present for the component of the same rank stored at the preceding iteration or at an earlier iteration.

4. The method as claimed in claim 1, wherein the step consisting in calculating the SISO decoding output value consists, for any bit of rank j∈[o, n],
if the value of the analog weight components of the weight vectors is different from the start-up value, +∞, in calculating the probability of the value of the corresponding bit of rank j expressed as the difference between the analog weight values;
if not, if the value of the analog weight component of one of the weight vectors is the only one different from the start-up value, +∞, in allocating a first given value to the probability of the value of the bit of rank j;
if not, if the value of the analog weight component of the other of the weight vectors is the only one different from the start-up value, +∞, in allocating a second given value, in opposition to said first given value, to the probability of the value of the bit of rank j.

5. A device for iteratively decoding block codes by the SISO decoding of a received produced code word consisting of n bits from test words, wherein said device comprises, at least for the processing of each received product code word:
a) means for generating, from an iterative algorithm, a plurality of decoded test words;
b) means for calculating, for each decoded test word, the analog weight expressed as the half-sum of the products of the value of each bit mapped to ±1 of this decoded test word and the probability of this value, in terms of log-likelihood;
c) means for sorting, by classification, said analog weight values for the decoded test words, in order to produce a first analog weight vector formed by the analog weight components of the decoded test words, the bit of rank j of which is at a first value, and a second analog weight vector formed by the analog weight components of the decoded test words, the bit of rank j of which is at a second value;
d₁) a first and a second register allowing said classified analog weight values to be stored according to said first or said second analog weight vector respectively;
d₂) means for calculating the SISO decoding soft-decision output value, comprising at least one module for subtracting the analog weight components from the first and the second analog weight vector.

6. The method as claimed in claim 2, wherein the step consisting in calculating the SISO decoding output value consists, for any bit of rank j∈[o, n],
if the value of the analog weight components of the weight vectors is different from the start-up value, +∞, in calculating the probability of the value of the corresponding bit of rank j expressed as the difference between the analog weight values;
if not, if the value of the analog weight component of one of the weight vectors is the only one different from the start-up value, +∞, in allocating a first given value to the probability of the value of the bit of rank j;
if not, if the value of the analog weight component of the other of the weight vectors is the only one different from the start-up value, +∞, in allocating a second given value, in opposition to said first given value, to the probability of the value of the bit of rank j.

7. The method as claimed in claim 3, wherein the step consisting in calculating the SISO decoding output value consists, for any bit of rank j∈[o, n],
if the value of the analog weight components of the weight vectors is different from the start-up value, +∞, in calculating the probability of the value of the corresponding bit of rank j expressed as the difference between the analog weight values;
if not, if the value of the analog weight component of one of the weight vectors is the only one different from the start-up value, +∞, in allocating a first given value to the probability of the value of the bit of rank j;
if not, if the value of the analog weight component of the other of the weight vectors is the only one different from the start-up value, +∞, in allocating a second given value, in opposition to said first given value, to the probability of the value of the bit of rank j.
